(19) United States
(12) Patent Application Publication
(10) Pub. No.: US 2013/0206593 A1
(43) Pub. Date: Aug. 15, 2013

(54) FERROMAGNETIC MATERIAL SPUTTERING TARGET

(71) Applicants: Atsutoshi Arakawa, Ibaraki (JP); Yuki Ikeda, Ibaraki (JP)

(72) Inventors: Atsutoshi Arakawa, Ibaraki (JP); Yuki Ikeda, Ibaraki (JP)

(73) Assignee: JX NIPPON MINING & METALS CORPORATION, Tokyo (JP)

(21) Appl. No.: 13/882,233

(22) PCT Filed: Dec. 15, 2011
(86) PCT No.: PCT/JP2011/079056

§ 371 Date: Apr. 29, 2013

(30) Foreign Application Priority Data
Dec. 17, 2010 (JP) 2010-281728

(51) Int. Cl. C23C 14/34

(52) U.S. Cl. CPC C23C 14/3414
USPC 204/298.13

(57) ABSTRACT

Provided is a ferromagnetic material sputtering target comprising a metal having a composition that Cr is contained in an amount of 20 mol % or less, Ru is contained in an amount of 0.5 mol % or more and 30 mol % or less, and the remainder is Co, wherein the target has a structure including a base metal (A) and, within the base metal (A), a Co—Ru alloy phase (B) containing 35 mol % or more of Ru. The present invention provides a ferromagnetic material sputtering target that can improve leakage magnetic flux to allow stable discharge with a magnetron sputtering apparatus.

### TECHNICAL FIELD

The present invention relates to a ferromagnetic material sputtering target that is used for forming a magnetic material thin film of a magnetic recording medium, in particular, a magnetic recording layer of a hard disk employing a perpendicular magnetic recording system, and relates to a nonmagnetic-grain-dispersed ferromagnetic material sputtering target that provides a large leakage magnetic flux and can provide stable electric discharge in sputtering with a magnetron sputtering apparatus.

### BACKGROUND ART

In the field of magnetic recording represented by hard disk drives, ferromagnetic metal materials, i.e., Co, Fe, or Ni-based materials are used as materials of magnetic thin films that perform recording. For example, in recording layers of hard disks employing a longitudinal magnetic recording system, Co—Cr or Co—Cr—Pt ferromagnetic alloys of which main component is Co are used.

In recording layers of hard disks employing a perpendicular magnetic recording system that has been recently applied to practical use, composite materials each composed of a Co—Cr—Pt ferromagnetic alloy, of which main component is Co, and a nonmagnetic inorganic material are widely used.

In many cases, the magnetic thin film of a magnetic recording medium such as a hard disk is produced by sputtering a ferromagnetic material sputtering target consisting primarily of the above-mentioned material because of its high productivity.

Such a ferromagnetic material sputtering target can be produced by a melting process or a powder metallurgical process. Though a process to be employed is decided depending on the requirement in characteristics, the sputtering target composed of a ferromagnetic alloy and nonmagnetic inorganic grains, which is used when forming a recording layer of a hard disk of a perpendicular magnetic recording system, is generally produced by a powder metallurgical process. This is because since inorganic grains need to be uniformly dispersed in a base alloy, it is difficult to produce the sputtering target by a melting process.

For example, proposed is a method of preparing a sputtering target for magnetic recording media by: mechanically alloying an alloy powder having an alloy phase, which was produced by rapid solidification, and a powder constituting a ceramic phase; uniformly dispersing the powder constituting a ceramic phase within the alloy powder; and molding it with a hot press (Patent Document 1).

The target structure in this case appears to be such that the base material is bound in a milt (cod roe) shape and surrounded with SiO₂ (ceramics) (FIG. 2 of Patent Document 1) or SiO₂ is dispersed in the form of strings in the base material (FIG. 3 of Patent Document 1). Though other drawings are unclear, they look as though they show similar structures.

Such a structure has problems described below and is not a preferred sputtering target for magnetic recording media. Note that the spherical substance shown in FIG. 4 of Patent Document 1 is not a structure constituting the target but a mechanically alloyed powder.

Without using an alloy powder produced by rapid solidification, a ferromagnetic material sputtering target also can be produced by weighing commercially available raw material powders as the respective components constituting a target so as to achieve a desired composition, mixing the powders by a known process with, for example, a ball mill, and molding and sintering the powder mixture with a hot press.

For example, proposed is a method of preparing a sputtering target for magnetic recording media by mixing a powder mixture prepared by mixing a Co powder, a Cr powder, a TiO₂ powder and a SiO₂ powder, with a Co spherical powder with a planetary-screw mixer, and molding the resulting powder mixture with a hot press (Patent Document 2).

The target structure in this case appears to be such that a metal phase (B) of spherical shape is present in a phase (A) as a base metal in which inorganic grains are uniformly dispersed (FIG. 1 of Patent Document 2). In such a structure, the leakage magnetic flux is not sufficiently improved in some cases depending on the content rate of the constituent elements such as Co and Cr. Thus, the target structure is not preferred as a sputtering target for magnetic recording media.

Furthermore, proposed is a method of preparing a sputtering target for thin films of magnetic recording medium by mixing a Co—Cr binary alloy powder, a Pt powder and a SiO₂ powder, and hot-pressing the resulting powder mixture (Patent Document 3).

It is described that the target structure in this case has a Pt phase, a SiO₂ phase and a Co—Cr binary alloy phase, and that a dispersion layer is observed in the periphery of the Co—Cr binary alloy layer (not shown in drawing). Such a structure is also not preferred as a sputtering target for magnetic recording media.

There are sputtering apparatuses of various systems. In formation of the magnetic recording films, magnetron sputtering apparatuses equipped with DC power sources are widely used because of their high productivity. Sputtering is a method of generating an electric field by applying a high voltage between a substrate serving as a positive electrode and a target serving as a negative electrode disposed so as to face each other under an inert gas atmosphere.

On this occasion, the inert gas is ionized into plasma composed of electrons and positive ions. The positive ions in the plasma collide with the surface of the target (negative electrode) to make the target constituent atoms eject from the target and to allow the ejected atoms to adhere to the facing substrate surface to form a film. Sputtering is based on the principle that a film of the material constituting a target is formed on a substrate by such a series of actions.

Patent Document 1: Japanese Laid-Open Patent Publication No. H10-88333

Patent Document 2: Japanese Patent Application No. 2010-011326

Patent Document 3: Japanese Laid-Open Patent Publication No. 2009-1860

### SUMMARY OF INVENTION

### Technical Problem

In general, in sputtering of a ferromagnetic material sputtering target with a magnetron sputtering apparatus, most of the magnetic flux from a magnet passes through the target made of a ferromagnetic material to reduce the leakage magnetic flux, resulting in a big problem of no discharge or unstable discharge in sputtering.

In order to solve this problem, a reduction in content of Co, which is a ferromagnetic metal, is suggested. A reduction in Co content, however, does not allow formation of a desired magnetic recording film and is therefore not an essential solution. Though it is possible to increase the leakage magnetic flux by reducing the thickness of the target, in this case, the target lifetime is shortened to require frequent replacement of the target, which causes an increase in the cost.

In view of the problems mentioned above, it is an object of the present invention to provide a nonmagnetic-grain-dispersed ferromagnetic material sputtering target of which the leakage magnetic flux is increased to allow stable discharge with a magnetron sputtering apparatus.

### Solution to Problem

In order to solve the above-mentioned problems, the present inventors have performed diligent studies and, as a result, have found that a target providing a large leakage magnetic flux can be obtained by regulating the composition and structural constitution of the target,

Accordingly, based on the findings, the present invention provides:

1) a ferromagnetic material sputtering target comprising a metal having a composition that Cr is contained in an amount of 20 mol % or less, Ru is contained in an amount of 0.5 mol % or more and 30 mol % or less, and the remainder is Co, wherein the target has a structure including a base metal (A) and, within the base metal (A), a Co—Ru alloy phase (B) containing 35 mol % or more of Ru.

The present invention further provides:

2) a ferromagnetic material sputtering target comprising a metal having a composition that Cr is contained in an amount of 20 mol % or less, Ru is contained in an amount of 0.5 mol % or more and 30 mol % or less, Pt is contained in an amount of 0.5 mol % or more, and the remainder is Co, wherein the target has a structure including a base metal (A) and, within the base metal (A), a Co—Ru alloy phase (B) containing 35 mol % or more of Ru.

The present invention further provides:

3) the ferromagnetic material sputtering target according to 1) or 2) above, wherein 0.5 mol % or more and 10 mol % or less of at least one element selected from B, Ti, V, Mn, Zr, Nb, Mo, Ta, W, Si, and Al is contained as additive element.

The present invention further provides:

4) the ferromagnetic material sputtering target according to any one of 1) to 3) above, wherein the base metal (A) contains at least one inorganic material component selected from carbon, oxides, nitrides, carbides, and carbonitrides.

The present invention further provides:

5) the ferromagnetic material sputtering target according to 4) above, wherein the inorganic material is at least one oxide of element selected from Cr, Ta, Si, Ti, Zr, Al, Nb, B, and Co, and the volume proportion of the nonmagnetic material is 20 to 35 vol %.

The present invention further provides:

6) the ferromagnetic material sputtering target according to any one of 1) to 5) above, wherein the Co—Ru alloy phase (B) has an average grain size larger than that of the base metal (A), and the difference between these average grain sizes is 50 μm or more.

The present invention further provides:

7) the ferromagnetic material sputtering target according to any one of 1) to 6) above, wherein the relative density is 97% or more.

### Advantageous Effects of Invention

The nonmagnetic-grain-dispersed ferromagnetic material sputtering target of the present invention, which was thus prepared, provides a large leakage magnetic flux to efficiently accelerate ionization of an inert gas to achieve stable discharge when used in a magnetron sputtering apparatus. It is possible to increase the thickness of the target to enable a reduction in frequency of replacement of the target, resulting in an advantage that a magnetic material thin film can be produced with a low cost.

### DESCRIPTION OF EMBODIMENTS

The main component constituting a ferromagnetic material sputtering target of the present invention is: a metal having a composition that Cr is contained in an amount of 20 mol % or less, Ru is contained in an amount of 0.5 mol % or more and 30 mol % or less, and the remainder is Co; or a metal having a composition that Cr is contained in an amount of 20 mol % or less, Ru is contained in an amount of 0.5 mol % or more and 30 mol % or less, Pt is contained in an amount of 0.5 mol % or more, and the remainder is Co.

When the Ru content is 0.5 mol % or more, the effects of a magnetic material thin film can be obtained. Accordingly, the lower limit is determined to be 0.5 mol %. In contrast, since a too large amount of Ru is unfavorable because of its characteristics as a magnetic material, the upper limit is determined to be 30 mol %.

Cr is an indispensable component, and the content is higher than 0 mol %. That is, the Cr content is higher than the analyzable lower limit. Furthermore, as long as the Cr content is 20 mol % or less, the effects can be obtained even if the amount of Cr is small.

The amount of Pt is desirably 45 mol % or less. An excessive amount of Pt decreases the characteristics as a magnetic material, and Pt is expensive. Accordingly, a smaller amount of Pt is desirable from the viewpoint of manufacturing cost.

The ferromagnetic material sputtering target of the present invention can further comprise 0.5 mol % or more and 10 mol % or less of at least one element selected from B, Ti, V, Mn, Zr, Nb, Ru, Mo, Ta, W, Si, and Al as additive element. These elements are optionally added to the target material for improving the characteristics of a magnetic recording medium. The blending ratios can be variously adjusted within the above-mentioned ranges, while maintaining the characteristics as an effective magnetic recording medium.

The 0.5 mol % or more and 10 mol % or less of at least one element selected from B, Ti, V, Mn, Zr, Nb, Ru, Mo, Ta, W, Si, and Al is basically present in the base metal (A), but may slightly disperse into the Co—Ru alloy phase (B) described below through the interface with the phase (B). The present invention also entails such a case.

An important point of the present invention is that the structure of the target comprises a base metal (A) and, within the base metal (A), a Co—Ru alloy phase (B) containing 35 mol % or more of Ru. The phase (B) has a maximum magnetic permeability lower than that of the structure surrounding the phase, and the phases are separated from each other by the base metal (A).

In the target having such a structure, though the reasons of the improvement in leakage magnetic flux are not necessarily obvious at the present moment, it is believed that a portion with high magnetic flux density and a portion with low magnetic flux density are generated inside the target to cause an increase in magnetostatic energy compared with the structure having a uniform magnetic permeability, and thereby leakage of the magnetic flux to the outside of the target may become energetically advantageous.

The phase (B) desirably has a diameter of 10 to 150 μm. In the base metal (A), the phase (B) and fine inorganic grains are present. If the diameter of the phase (B) is less than 10 μm, the difference in size with the inorganic grains is small, and therefore, it accelerates diffusion between the phase (B) and the base metal (A) during sintering of the target material.

The progress of the diffusion makes the difference in structural component between the base metal (A) and the phase (B) unclear. Accordingly, the diameter of the phase (B) is preferably 10 μm or more, and more preferably 30 μm or more.

If the diameter exceeds 150 μm, the progress of sputtering decreases the smoothness of the target surface and disturbs the balance with the phase (A) as a matrix, and thereby causes a problem of particles. Accordingly, the diameter of the phase (B) is desirably 150 μm or less.

All of these are means for increasing the leakage magnetic flux. The leakage magnetic flux also can be controlled by the amounts and types of additive metals and inorganic grains. Accordingly, the above-described size of the phase (B) should not be necessarily satisfied, but is one of favorable conditions.

Even if the proportion of the phase (B) to the total volume of the target or to the volume or area of the erosion surface of the target is small (e.g., about 1%), the effect of a certain level can be obtained. In order to obtain a sufficient effect by the phase (B), however, the proportion of the phase (B) to the total volume of the target or to the volume or area of the erosion surface of the target is desirably 10% or more. The leakage magnetic flux can be increased by the presence of many phases (B).

In some target compositions, the proportion of the phase (B) to the total volume of the target or to the volume or area of the erosion surface of the target can be 50% or more, or further 60% or more. These volume or area proportions can be appropriately adjusted depending on the composition of the target. The present invention also entails such cases. Incidentally, the phase (B) in the present invention may have any shape, and the average grain size means the medium between the shortest diameter and the longest diameter.

The composition of the phase (B) is different from that of the base metal (A). Therefore, the composition in the periphery of the phase (B) may slightly change from that of the phase (B) by diffusion of elements during sintering.

In the range of a phase having a shape similar to that of the phase (B) of which diameters (major axis and minor axis) are each reduced to two-thirds thereof, the purpose can be achieved as long as the phase (B) is made of a Co—Ru alloy containing 35 mol % or more of Ru. The present invention entails such cases, and the purpose of the present invention can be achieved under such conditions.

Furthermore, the ferromagnetic material sputtering target of the present invention may contain at least one inorganic material, which is dispersed in the base metal, selected from carbon, oxides, nitrides, carbides, and carbonitrides. In such a case, the target has characteristics suitable as a material for a magnetic recording film having a granular structure, in particular, a recording film for a hard disk drive employing a perpendicular magnetic recording system.

Furthermore, as the inorganic material, at least one oxide of element selected from Cr, Ta, Si, Ti, Zr, Al, Nb, B, and Co is effective. The volume proportion of the nonmagnetic material can be 20 to 35%. In the case of an oxide of Cr, the amount of Cr oxide is distinguished from the amount of Cr added as a metal and is determined as a volume proportion as a chromium oxide.

The nonmagnetic grains are usually dispersed in the base metal (A), but some of them may adhere to the circumference of the phase (B) or become incorporated into the phase (B) during production of a target. The nonmagnetic grains in such a case, if the amount is small, do not affect the magnetic characteristics of the phase (B) and do not inhibit the purpose.

Furthermore, in the ferromagnetic material sputtering target, the Co—Ru alloy phase (B) can have an average grain size larger than that of the base metal (A), and the difference between these average grain sizes can be controlled to be 50 μm or more. As described above, though the diameter of the phase (B) can be adjusted to 10 to 150 μm, in order to improve the leakage magnetic flux density (PTF), it is more effective that the Co—Ru alloy phase (B) has an average grain size larger than that of the base metal (A) by 50 μm or more.

The ferromagnetic material sputtering target of the present invention more desirably has a relative density of 97% or more. It is generally known that a target having a higher density can reduce the amount of particles occurring during sputtering. Also in the present invention, a higher density is preferred. In the present invention, a relative density of 97% or more can be achieved.

The relative density in the present invention is a value determined by dividing the measured density of a target by the calculated density (theoretical density). The calculated density is a density assuming the structural components of a target coexist without diffusing to or reacting with each other, and is calculated by the following expression:

Expression: calculated density=Σ[(molecular weight of a structural component)×(molar ratio of the structural component)]/Σ[(molecular weight of the structural component)×(molar ratio of the structural component)/(literature density of the structural component)], wherein Σ is the sum of the values of all structural components of the target.

The thus prepared target provides a large leakage magnetic flux. When the target is used in a magnetron sputtering apparatus, ionization of an inert gas is efficiently accelerated to achieve stable discharge. It is possible to increase the thickness of the target to enable a reduction in frequency of replacement of the target, resulting in an advantage that a magnetic material thin film can be produced with a low cost. Furthermore, the increase in density has an advantage of reducing the particle generation that causes a reduction in yield.

The ferromagnetic material sputtering target of the present invention can be produced by a powder metallurgy process. First, a powder of a metal element or alloy (note that a Co—Ru alloy powder is indispensable for forming the phase (B)) and, as necessary, an additive metal element powder or inorganic material powder are prepared.

Each metal element powder may be produced by any method. The maximum grain sizes of these powders are each desirably 20 μm or less, whereas a too small grain size accelerates oxidation to cause problems such that the component composition is outside the necessary range. Accordingly, the size is desirably 0.1 μm or more.

Subsequently, the metal powder and the alloy powder are weighed to achieve a desirable composition and are mixed and pulverized with a known procedure using, for example, a ball mill. When an inorganic material powder is also added, the powder may be mixed with the metal powder and the alloy powder in this stage.

The inorganic material powder is a carbon powder, an oxide powder, a nitride powder, a carbide powder, or a carbonitride powder. The inorganic material powder desirably has a maximum grain size of 5 μm or less, whereas a too small grain size tends to cause agglomeration. Accordingly, the size is further desirably 0.1 μm or more.

The Co—Ru powder can be prepared by sintering a powder mixture of a Co powder and a Ru powder and then pulverizing and sieving the sintered product. The pulverization is desirably performed with a high-energy ball mill. The thus prepared Co—Ru powder having a diameter in a range of 30 to 150 μm is mixed with a metal powder prepared in advance and an optionally selected inorganic material powder with a mixer. The mixer is preferably a planetary-screw mixer or planetary-screw mixing agitator. In addition, considering the problem of oxidation during mixing, the mixing is preferably performed in an inert gas atmosphere or in vacuum.

The high-energy ball mill can pulverize and mix raw material powders within a short time compared with a ball mill or a vibration mill.

The thus prepared powder is molded and sintered with a vacuum hot press apparatus, followed by machining into a desired shape to provide a ferromagnetic material sputtering target of the present invention. The Co—Ru powder corresponds to the phase (B) that is observed in the target structure.

The molding and sintering is not limited to hot pressing and may be performed by spark plasma sintering or hot hydrostatic pressing. The retention temperature for the sintering is preferably set to the lowest temperature in the temperature range in which the target is sufficiently densified. Though it depends on the composition of a target, in many cases, the temperature is in the range of 800 to 1300° C. The pressure in the sintering is preferably 300 to 500 kg/cm².

### EXAMPLES

The present invention will now be described by Examples and Comparative Examples. The Examples are merely illustrative, and the present invention shall in no way be limited thereby. In other words, the present invention shall only be limited by the scope of claim for a patent, and shall include the various modifications other than the Examples of this invention.

### Example 1 and Comparative Example 1

In Example 1, a Co powder having an average grain size of 3 μm, a Cr powder having an average grain size of 6 μm, a Pt powder having an average grain size of 3 μm, a CoO powder having an average grain size of 2 μm, a SiO₂ powder having an average grain size of 1 μm, and a Co-45Ru (mol %) powder having a diameter in the range of 50 to 150 μm were prepared as raw material powders.

These powders were weighed at weight proportions of 33.46 wt % of the Co powder, 2.83 wt % of the Cr powder, 31.86 wt % of the Pt powder, 4.64 wt % of the CoO powder, 5.20 wt % of the SiO₂ powder, and 22.01 wt % of the Co—Ru powder to obtain a target having a composition of 88(Co-5Cr-15Pt-9Ru)-5CoO-7SiO₂ (mol %).

Subsequently, the Co powder, the Co powder, the Pt powder, and the SiO₂ powder were placed in a 10-liter ball mill pot together with zirconia balls as a pulverizing medium, and the mill pot was rotated for 20 hours for mixing. The resulting powder mixture was further mixed with the Co—Ru powder with a planetary-screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to obtain a disk-shaped target having a diameter of 180 mm and a thickness of 5 mm.

The leakage magnetic flux was measured based on ASTM F2086-01 (Standard Test Method for Pass Through Flux of Circular Magnetic Sputtering Targets, Method 2). The target was fixed at the center thereof and was rotated by 0, 30, 60, 90, and 120 degrees, and the leakage magnetic flux density of the target was measured at each degree of angle and was divided by the reference field value defined by ASTM and multiplied by 100 to obtain a percentage value. The average value of the five points is shown in Table 1 as the average leakage magnetic flux density (PTF (%)).

In Comparative Example 1, a Co powder having an average grain size of 3 μm, a Cr powder having an average grain size of 6 μm, a Pt powder having an average grain size of 3 μm, a Ru powder having an average grain size of 10 μm, a CoO powder having an average grain size of 2 μm, and a SiO₂ powder having an average grain size of 1 μm were prepared as raw material powders. These powders were weighed at weight proportions of 45.56 wt % of the Co powder, 2.83 wt % of the Cr powder, 31.86 wt % of the Pt powder, 9.90 wt % of the Ru powder, 4.64 wt % of the CoO powder, and 5.20 wt % of the SiO₂ powder to obtain a target having a composition of 88(Co-5Cr-15Pt-9Ru)-5CoO-7SiO₂(mol %).

These powders were placed in a 10-liter ball mill pot together with zirconia balls as a pulverizing medium, and the mill pot was rotated for 20 hours for mixing.

Subsequently, the resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to obtain a disk-shaped target having a diameter of 180 mm and a thickness of 5 mm. The average leakage magnetic flux density of the target was measured. The result is shown in Table 1.

TABLE 1

| | | | | | Relative |
|---|---|---|---|---|---|
| No. | Target composition (mol %) | Phase (B) | Size | PTF (%) | density (%) |
| Example 1 | 88(Co—5Cr—15Pt—9Ru)—5CoO—7SiO₂ | Grain size: 30 to 100 μm; | φ 180 × 5t | 45.5 | 98.5 |
| | | Co—45 mol % Ru | | | |
| Comparative | 88(Co—5Cr—15Pt—9Ru)—5CoO—7SiO₂ | None | φ 180 × 5t | 39.1 | 98.4 |
| Example 1 | | | | | |

As shown in Table 1, the average leakage magnetic flux density of the target of Example 1 was 45.5%, which was larger than 39.1%, of Comparative Example 1, and was confirmed to be considerably improved. In Example 1, the relative density was 98.5%. Thus, a target having a high density of exceeding 97% was obtained.

The polished surface of the target of Example 1 was observed, and portions corresponding to SiO₂ grains could be confirmed in the target structure. It was further confirmed that large phases not containing SiO₂ grains were dispersed in the matrix in which SiO₂ grains were finely dispersed. The phase corresponds to the phase (B) of the present invention and is made of a Co—Ru alloy containing 45 mol % of Ru. Difference in the average grain size of the phase (B) and the phase (A) was 60 μm or more.

In contrast, in Comparative Example 1, coarse phases having an average grain size larger than that of the phase (A) by 50 μm or more were not observed at all in the matrix of the target in which SiO₂ grains are dispersed. As shown in Table 1, the average leakage magnetic flux density (PTF) in Comparative Example 1 thereby decreased to 39.1%. Accordingly, it was found the presence of the phase (B) observed in Example 1 is effective.

### Example 2

In Example 2, a Co powder having an average grain size of 3 μm, a Cr powder having an average grain size of 6 μm, a CoO powder having an average grain size of 2 μm, a SiO₂ powder having an average grain size of 1 μm, and a Co-45Ru (mol %) powder having a diameter in the range of 50 to 150 μm were prepared as raw material powders.

These powders were weighed at weight proportions of 55.40 wt % of the Co powder, 3.64 wt % of the Cr powder, 5.96 wt % of the CoO powder, 6.69 wt % of the SiO₂ powder, and 28.30 wt % of the Co—Ru powder to obtain a target having a composition of 88(Co-5Cr-9Ru)-5CoO-7SiO₂ (mol %).

Subsequently, the Co powder, the Cr powder, the CoO powder, and the SiO₂ powder were placed in a 10-liter ball mill pot together with zirconia balls as a pulverizing medium, and the mill pot was rotated for 20 hours for mixing. The resulting powder mixture was further mixed with the Co—Ru powder with a planetary-screw mixer having a ball capacity of about 7 liters for 10 minutes.

The resulting powder mixture was charged in a carbon mold and was hot-pressed in a vacuum atmosphere under conditions of a temperature of 1050° C., a retention time of 2 hours, and a pressure of 30 MPa to obtain a sintered compact. The sintered compact was ground with a surface grinder to obtain a disk-shaped target having a diameter of 180 mm and a thickness of 5 mm. The average leakage magnetic flux density of the target was measured. The results are shown in Table 2.

TABLE 2

| | | | | | Relative |
|---|---|---|---|---|---|
| No. | Target composition (mol %) | Phase (B) | Size | PTF (%) | density (%) |
| Example 2 | 88(Co—5Cr—9Ru)—5CoO—7SiO₂ | Grain size: 30 to 100 μm; Co—45 mol % Ru | φ 180 × 5t | 42.5 | 98.5 |

As shown in Table 2, the average leakage magnetic flux density of the target of Example 2 was 42.5%. In addition, the relative density was 98.5%. Thus, a target having a high density of exceeding 97% was obtained.

As in Example 1, the polished surface of the target of Example 2 was observed, and portions corresponding to SiO₂ grains could be confirmed in the target structure. It was further confirmed that large phases not containing SiO₂ grains were dispersed in the matrix in which SiO₂ grains were finely dispersed. The phase corresponds to the phase (B) of the present invention and is made of a Co—Ru alloy containing 45 mol % of Ru. Difference in the average grain size of the phase (B) and the phase (A) was 60 μm or more.

The above-described Examples show an example of a target having a composition of 88(Co-5Cr-15Pt-9Ru)-5CoO-7SiO₂ (mol %) and an example of a target having a composition of 88(Co-5Cr-9Ru)-5CoO-7SiO₂ (mol %). It was confirmed that similar effects can be obtained even if the composition ratio is changed within the range of the present invention.

In the above-described Examples, Ru alone is added; however, the target may contain at least one element selected from B, Ti, V, Mn, Zr, Nb, Ru, Mo, Ta, W, Si, and Al as additive element, and all of such targets can maintain the characteristics as effective magnetic recording media. In other words, these elements are optionally added to target material for improving the characteristics of magnetic recording media. Though the effects in each case are not specially shown in Examples, it was confirmed that the effects were equivalent to those shown in Examples of the present invention.

Furthermore, though the above-described Examples show cases of adding oxide of Si, other oxides of Cr, Ta, Ti, Zr, Al, Nb, B, or Co show equivalent effects. In addition, though the above describes the cases of adding oxides, it was confirmed that nitrides, carbides, carbonitrides and carbon of these elements can show effects equivalent to those of oxides.

### INDUSTRIAL APPLICABILITY

The present invention enables notable improvement in leakage magnetic flux by regulating the structural constitution of a ferromagnetic material sputtering target. Accordingly, the use of a target of the present invention can give stable discharge in sputtering with a magnetron sputtering apparatus. Furthermore, it is possible to increase the thickness of a target, and thereby the target lifetime becomes long to allow production of a magnetic material thin film at a low cost.

The target of the present invention is useful as a ferromagnetic material sputtering target that is used for forming a magnetic material thin film of a magnetic recording medium, in particular, a recording layer of a hard disk drive.

1. A ferromagnetic material sputtering target comprising a metal having a composition that Cr is contained in an amount of 20 mol % or less, Ru is contained in an amount of 0.5 mol % or more and 30 mol % or less, and the remainder is Co, wherein the target has a structure including a base metal (A) and, within the base metal (A), a Co—Ru alloy phase (B) containing 35 mol % or more of Ru.

2. A ferromagnetic material sputtering target comprising a metal having a composition that Cr is contained in an amount of 20 mol % or less, Ru is contained in an amount of 0.5 mol % or more and 30 mol % or less, Pt is contained in an amount of 0.5 mol % or more, and the remainder is Co, wherein the target has a structure including a base metal (A) and, within the base metal (A), a Co—Ru alloy phase (B) containing 35 mol % or more of Ru.

3. The ferromagnetic material sputtering target according to claim 2, wherein 0.5 mol % or more and 10 mol % or less of at least one element selected from the group consisting of B, Ti, V, Mn, Zr, Nb, Mo, Ta, W, Si, and Al is contained as additive element.

4. The ferromagnetic material sputtering target according to claim 3, wherein the base metal (A) contains at least one inorganic material component selected from the group consisting of carbon, oxides, nitrides, carbides, and carbonitrides.

5. The ferromagnetic material sputtering target according to claim 4, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 35%.

6. The ferromagnetic material sputtering target according to claim 4, wherein the Co—Ru alloy phase (B) has an average grain size larger than that of the base metal (A), and the difference between these average grain sizes is 50 μm or more.

7. The ferromagnetic material sputtering target according to claim 6, wherein the sputtering target has a relative density of 97% or more.

8. The ferromagnetic material sputtering target according to claim 2, wherein the base metal (A) contains at least one inorganic material component selected from the group consisting of carbon, oxides, nitrides, carbides, and carbonitrides.

9. The ferromagnetic material sputtering target according to claim 8, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 35%.

10. The ferromagnetic material sputtering target according to claim 8, wherein the Co—Ru alloy phase (B) has an average grain size larger than that of the base metal (A), and the difference between these average grain sizes is 50 μm or more.

11. The ferromagnetic material sputtering target according to claim 2, wherein the sputtering target has a relative density of 97% or more.

12. The ferromagnetic material sputtering target according to claim 1, wherein 0.5 mol % or more and 10 mol % or less of at least one element selected from the group consisting of B, Ti, V, Mn, Zr, Nb, Mo, Ta, W, Si, and Al is contained as an additive element.

13. The ferromagnetic material sputtering target according to claim 12, wherein the base metal (A) contains at least one inorganic material component selected from the group consisting of carbon, oxides, nitrides, carbides, and carbonitrides.

14. The ferromagnetic material sputtering target according to claim 13, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 35%.

15. The ferromagnetic material sputtering target according to claim 13, wherein the Co—Ru alloy phase (B) has an average grain size larger than that of the base metal (A), and the difference between these average grain sizes is 50 μm or more.

16. The ferromagnetic material sputtering target according to claim 15, wherein the sputtering target has a relative density of 97% or more.

17. The ferromagnetic material sputtering target according to claim 1, wherein the base metal (A) contains at least one inorganic material component selected from the group consisting of carbon, oxides, nitrides, carbides, and carbonitrides.

18. The ferromagnetic material sputtering target according to claim 17, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 35%.

19. The ferromagnetic material sputtering target according to claim 17, wherein the Co—Ru alloy phase (B) has an average grain size larger than that of the base metal (A), and the difference between these average grain sizes is 50 μm or more.

20. The ferromagnetic material sputtering target according to claim 1, wherein the sputtering target has a relative density of 97% or more.
